(19) United States
(12) Patent Application Publication
(10) Pub. No.: US 2024/0192584 A1
(43) Pub. Date: Jun. 13, 2024

(54) BLANK MASK AND PHOTOMASK USING THE SAME

(71) Applicant: SK enpulse Co., Ltd., Pyeongtaek-si (KR)

(72) Inventors: Hyung-joo LEE, Seoul (KR); Kyuhun KIM, Suwon-si (KR); GeonGon LEE, Seoul (KR); Seong Yoon KIM, Seoul (KR); Suk Young CHOI, Seoul (KR); Suhyeon KIM, Seoul (KR); Sung Hoon SON, Seoul (KR); Min Gyo JEONG, Seoul (KR); Inkyun SHIN, Seoul (KR)

(73) Assignee: SK enpulse Co., Ltd., Pyeongtaek-si (KR)

(21) Appl. No.: 18/080,186

(22) Filed: Dec. 13, 2022

(30) Foreign Application Priority Data
Dec. 15, 2021 (KR) 10-2021-0179867

(51) Int. Cl. G03F 1/50; G02F 1/00; G02F 1/1335; G03F 1/60; G03F 1/80; H01L 21/285

(52) U.S. Cl. CPC G03F 1/50; G02F 1/0063; G02F 1/133512; G03F 1/60; G03F 1/80; H01L 21/28568

(57) ABSTRACT

A blank mask includes a light-transmitting substrate; and a light-shielding film, disposed on the light-transmitting substrate, including a first light-shielding layer and a second light-shielding layer disposed on the first light-shielding layer. The second light-shielding layer includes at least one of a transition metal, oxygen, or nitrogen, or any combination thereof. A reflectance of a surface of the light-shielding film with respect to light having a wavelength of 193 nm is 20% or more and 40% or less. A hardness value of the second light-shielding layer is 0.3 kPa or more and 0.55 kPa or less.

### CROSS-REFERENCE TO RELATED APPLICATION

This application claims the benefit under 35 USC 119(a) of Korean Patent Application No. 10-2021-0179867, filed on Dec. 15, 2021, the disclosure of which is incorporated herein by reference in its entirety.

### BACKGROUND

### 1. Field

The embodiment relates to a blank mask and a photomask using the same.

### 2. Discussion of Related Art

Due to the high integration of semiconductor devices or the like, miniaturization of a circuit pattern of the semiconductor devices is desired. For this reason, the importance of a lithography technique, which is a technique for developing a circuit pattern on a wafer surface using a photomask, is further emphasized.

In order to develop a miniaturized circuit pattern, an exposure light source used in an exposure process is required for using a short wavelength. As the recently used exposure light sources, there are ArF excimer lasers (wavelength 193 nm) or the like.

Meanwhile, as the photomasks, there are binary masks, phase shift masks, or the like.

A binary mask has a configuration in which a light-shielding layer pattern is formed on a light-transmitting substrate. In the binary mask, on a surface in which a pattern is formed, a transmissive portion, not including a light-shielding layer, transmits exposure light, and a light-shielding portion, including the light-shielding film blocks the exposure light, thereby exposing a pattern on a resist film formed on a wafer surface. However, as the pattern becomes finer in the binary mask, a problem may occur in a fine pattern phenomenon due to the diffraction of light generated at the edge of the transmissive portion in the exposure process.

The phase shift masks include a Levenson type, an outrigger type, and a half-tone type. Among them, the half-tone phase shift mask has a configuration in which a pattern formed of a semi-transmissive film is formed on a light-transmitting substrate. In the half-tone phase shift mask, on the surface on which the pattern is formed, the transmissive portion, not including a transflective layer, transmits exposure light, and a transflective portion, including the transflective layer, transmits attenuated exposure light. There is a phase difference between the attenuated exposure light and the exposure light passing through the transmissive portion. Due to this, the diffracted light generated at the edge of the transmissive portion is canceled by the exposure light passing through the transflective portion, and thus the phase shift mask may form a sophisticated fine pattern on the wafer surface.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a blank mask includes a light-transmitting substrate; and a light-shielding film, disposed on the light-transmitting substrate, including a first light-shielding layer and a second light-shielding layer disposed on the first light-shielding layer. The second light-shielding layer includes at least one of a transition metal, oxygen, or nitrogen, or any combination thereof. A reflectance of a surface of the light-shielding film with respect to light having a wavelength of 193 nm is 20% or more and 40% or less. A hardness value of the second light-shielding layer is 0.3 kPa or more and 0.55 kPa or less.

A reflectance of the surface of the light-shielding film with respect to light having a wavelength of 350 nm may be 25% or more and 45% or less.

A reflectance of the surface of the light-shielding film with respect to all light having a wavelength of 350 nm or more and 400 nm or less may be included in a range of 25% or more and 50% or less. A reflectance of the surface of the light-shielding film with respect to all light having a wavelength of 480 nm or more and 550 nm or less may be included in a range of 30% or more and 50% or less.

The hardness value of the second light-shielding layer may be 0.15 times or more and 0.55 times or less than a hardness value of the first light-shielding layer.

A Young's modulus value of the second light-shielding layer may be 1.0 kPa or more.

A Young's modulus value of the second light-shielding layer may be 0.15 times or more and 0.55 times or less than a Young's modulus value of the first light-shielding layer.

An absolute value of a value obtained by subtracting a transition metal content of the first light-shielding layer from a transition metal content of the second light-shielding layer may be 30 at % or less.

A thickness ratio of the first light-shielding layer and the second light-shielding layer may be 1:0.02 to 0.25.

A film thickness of the second light-shielding layer may be 30 to 200 Å.

The second light-shielding layer may include the transition metal at 35 at % or more and 75 at % or less.

The transition metal may include at least one selected from the group consisting of Cr, Ta, Ti, and Hf.

In another general aspect, a photomask includes a light-transmitting substrate; and a patterned light-shielding film, disposed on the light-transmitting substrate, comprising a first light-shielding layer and a second light-shielding layer disposed on the first light-shielding layer. The second light-shielding layer includes at least one of a transition metal, oxygen, or nitrogen, or any combination thereof. A reflectance of an upper surface of the patterned light-shielding film with respect to light having a wavelength of 193 nm is 20% or more and 40% or less. A hardness value of the second light-shielding layer is 0.3 kPa or more and 0.55 kPa or less.

In another general aspect, a method of manufacturing a semiconductor device, includes arranging a light source, a photomask, and a semiconductor wafer coated with a resist film; selectively transmitting and emitting light incident from the light source through the photomask on the semiconductor wafer; and developing a pattern on the semiconductor wafer. The photomask includes a light-transmitting substrate and a patterned light-shielding film disposed on the light-transmitting substrate. The patterned light-shielding film includes a first light-shielding layer and a second light-shielding layer disposed on the first light-shielding layer. The second light-shielding layer includes at least one of a transition metal and at least one of oxygen and nitrogen. A reflectance of an upper surface of the patterned light-shielding film with respect to light having a wavelength of 193 nm is 20% or more and 40% or less. A hardness value of the second light-shielding layer is 0.3 kPa or more and 0.55 kPa or less.

Other features and aspects will be apparent from the following detailed description, the drawings, and the claims.

### BRIEF DESCRIPTION OF THE DRAWINGS

FIG. 1 is a conceptual diagram illustrating a blank mask according to an embodiment disclosed in the present specification.

FIG. 2 is a conceptual diagram illustrating a patterned light-shielding film formed by patterning a light-shielding film.

FIG. 3 is a conceptual diagram illustrating a blank mask according to another embodiment disclosed herein.

FIG. 4 is a conceptual diagram illustrating a photomask according to still another embodiment disclosed herein.

FIG. 5 is a graph showing a value obtained by measuring a reflectance of a surface of a light-shielding film of Example 1 according to a wavelength of inspection light.

FIG. 6A illustrates an image obtained by measuring a surface of a light-shielding film of Comparative Example 1 by a defect inspector.

FIG. 6B illustrates an image obtained by measuring a surface of a light-shielding film of Comparative Example 2 by a defect inspector.

Throughout the drawings and the detailed description, the same reference numerals refer to the same or like elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The present disclosure is directed to provide a blank mask and the like from which a more accurate measurement value can be obtained when a high-sensitivity defect inspection is performed on a surface of a light-shielding film, and the amount of particles generated from the light-shielding film or the like is effectively reduced.

According to a blank mask of the embodiment, it is possible to obtain a more accurate measurement value when a high-sensitivity defect inspection is performed on a surface of a light-shielding film, and to effectively reduce the amount of particles generated from the light-shielding film or the like.

In the present specification, a pseudo defect refers to a defect that is determined as a defect when inspected by a high-sensitivity defect inspector although it does not correspond to an actual defect because the defect is located on a surface of a light-shielding film and does not cause a decrease in the resolution of a blank mask.

In this specification, a standard deviation refers to a sample standard deviation.

As semiconductors are highly integrated, it is required to form a finer circuit pattern on a semiconductor wafer. As the line width of a pattern developed on a semiconductor wafer is further reduced, an issue related to reducing the resolution of a photomask is also increasing.

High-sensitivity defect inspection may be performed on s surface of a light-shielding film or a patterned light-shielding film formed by patterning the light-shielding film. When high-sensitivity defect inspection is performed, a defect inspector may determine that a number of pseudo defects present on the surface of the light-shielding film or the patterned light-shielding film are defects, and may have difficulty in detecting actual defects. In this case, the production process efficiency of a blank mask and a photomask can be reduced, such as an additional inspection process is required to distinguish an actual defect from inspection result data.

To improve the accuracy of defect inspection of the light-shielding film or the patterned light-shielding film, a method of increasing the surface metal content of the light-shielding film may be applied. This may be one method of controlling optical properties, such as reflectance of the surface of the light-shielding film, to have appropriate values for defect inspection. However, the light-shielding film having a high surface metal content also has a problem in that the amount of particles generated after patterning increases. The particles may cause scratches on the surface of the patterned light-shielding film, and may cause a problem of lowering the resolution of the photomask.

The inventors of the embodiment have experimentally confirmed the fact that it is easy to detect defects during high-sensitivity defect inspection and provide a blank mask or the like in which the occurrence of defects is suppressed, by applying a light-shielding film of a multilayer structure and controlling the reflectance of the surface of the light-shielding film at a specific wavelength, and at the same time, controlling a hardness value for each layer in the light-shielding film.

Hereinafter, embodiments will be specifically described.

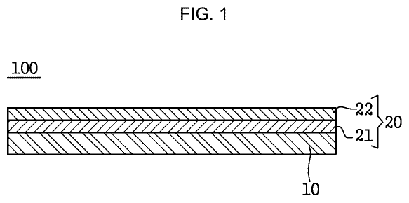

FIG. 1 is a conceptual diagram illustrating a blank mask according to an embodiment disclosed in the present specification. A blank mask of the embodiment will be described with reference to FIG. 1.

The blank mask 100 includes a light-transmitting substrate 10 and a light-shielding film 20 positioned on the light-transmitting substrate 10.

The material of the light-transmitting substrate 10 is not limited as long as the material has light transmittance with respect to exposure light and can be applied to the blank mask 100. Specifically, the transmittance of the light-transmitting substrate 10 with respect to the exposure light having a wavelength of 193 nm may be 85% or more. The transmittance may be 87% or more. The transmittance may be 99.99% or less. For example, the light-transmitting substrate 10 may be a synthetic quartz substrate. In this case, the light-transmitting substrate 10 may suppress the attenuation of light passing through the light-transmitting substrate 10.

In addition, the light-transmitting substrate 10 may suppress the occurrence of optical distortion by adjusting surface characteristics such as flatness and roughness.

The light-shielding film 20 may be positioned on a top side of the light-transmitting substrate 10.

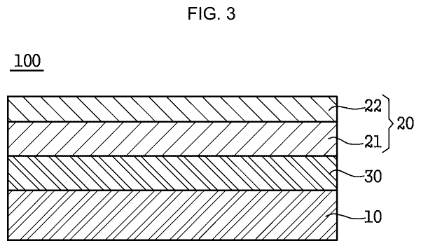

The light-shielding film 20 may have a characteristic of blocking at least a certain portion of the exposure light incident on a bottom side of the light-transmitting substrate 10. In addition, when a phase shift film 30 (see FIG. 3) or the like is positioned between the light-transmitting substrate 10 and the light-shielding film 20, the light-shielding film 20 may be used as an etching mask in a process of etching the phase shift film 30 or the like along a pattern shape.

The light-shielding film 20 may include a first light-shielding layer 21 and a second light-shielding layer 22 disposed on the first light-shielding layer 21.

The light-shielding film 20 includes at least one of a transition metal, oxygen, and nitrogen.

The second light-shielding layer 22 includes at least one of a transition metal, oxygen, and nitrogen.

The first light-shielding layer 21 and the second light-shielding layer 22 have different transition metal contents.

### Optical Characteristics and Mechanical Properties of Light-Shielding Film

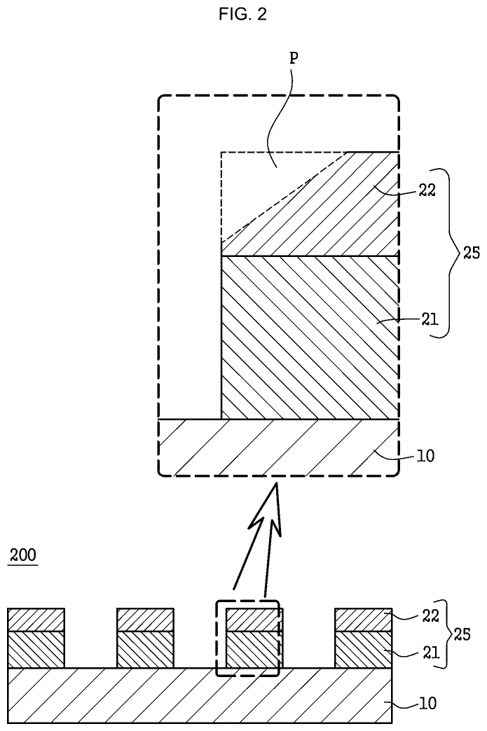

FIG. 2 is a conceptual diagram illustrating a patterned light-shielding film formed by patterning a light-shielding film. An embodiment will be described with reference to FIG. 2.

A reflectance of the surface of the light-shielding film 20 with respect to light having a wavelength of 193 nm is 20% or more and 40% or less, and a hardness value of the second light-shielding layer is 0.3 kPa or more and 0.55 kPa or less.

Defects on a surface of a patterned film (hereinafter, referred to as a patterned light-shielding film) formed by patterning the light-shielding film 20 may be detected using a defect inspector. Specifically, when inspection light irradiates to a surface of a patterned light-shielding film 25 through the defect inspector, reflected light is generated from the surface of the patterned light-shielding film 25. The defect inspector may analyze the reflected light to determine whether there is a defect at an inspection position.

The wavelength of the inspection light of the defect inspector may be different depending on an object to be measured. In general, the wavelength of the inspection light of the defect inspector for a photomask may be in the range of 190 nm or more and 260 nm or less, and the wavelength of the inspection light of the defect inspector for a blank mask may be in a range of 350 nm or more and 400 nm or less or in a range of 480 nm or more and 550 nm or less.

When the sensitivity of defect inspection is configured high, the intensity of reflected light formed during the inspection process may affect the accuracy of the defect inspection. Specifically, a large number of pseudo defects may be detected so that detection data corresponding to an actual defect may be ignored, or reflected light having excessively high intensity may be incident on an inspector lens to distort a measured surface image of the patterned light-shielding film 25.

A method of further increasing the transition metal content of the light-shielding film or the patterned light-shielding film 25 may be considered so that the reflected light having stronger intensity may be generated from the surface of the patterned light-shielding film 25. In this case, even if the sensitivity of the defect inspection is configured to be a high value, the frequency of detection of pseudo defects can be reduced, but the amount of particles generated from the light-shielding film or the patterned light-shielding film 25 can be increased after the process of patterning the light-shielding film or after the patterning is completed. Many of these particles may be generated from a damaged portion p of the patterned light-shielding film.

According to an embodiment, by simultaneously controlling the hardness value of the second light-shielding layer 22 and the reflectance of the surface of the light-shielding film 20 with respect to the light having a wavelength of 193 nm, it is possible to further improve the durability of the patterned light-shielding film of an upper corner of the patterned light-shielding film in addition to more accurately detecting an actual defect present on the surface of the patterned light-shielding film.

The reflectance of the surface of the light-shielding film and the hardness value of the second light-shielding layer may be adjusted by controlling a ratio of reactive gas applied when forming each light-shielding layer in the light-shielding film, reactive gas composition, sputtering power, atmospheric gas pressure, thermal processing, and cooling treatment conditions, etc.

The reflectance of the light-shielding film 20 is measured through a spectroscopic ellipsometer. The reflectance of the light-shielding film 20 may be measured using, for example, the MG-Pro model manufactured by Nano-View Co. Ltd.

Hardness may be measured with an atomic force microscope (AFM). Specifically, hardness is measured by applying cantilever model PPP-CONTSCR manufactured by Park Systems Corporation at a scan rate of 0.5 Hz and in a contact mode using AFM equipment (equipment model XE-150) manufactured by Park Systems Corporation. Adhesion energy at 16 points within an object to be measured may be measured to obtain an average value thereof, and a hardness value obtained from the average value may be used as the above hardness value. As a measuring tip applied during measurement, a Berkovich tip (Poisson's ratio of tip: 0.07) made of silicone is applied, and as the hardness measurement result, the Oliver and Pharr Model is applied and a value obtained by a program provided by AFM equipment company is taken and presented.

The reflectance of the surface of the light-shielding film 20 with respect to light having a wavelength of 193 nm may be 20% or more and 40% or less. The reflectance may be 22% or more. The reflectance may be 25% or more. The reflectance may be 27% or more. The reflectance may be 35% or less. The reflectance may be 33% or less.

The hardness of the second light-shielding layer 22 may be 0.3 kPa or more and 0.55 kPa or less. The hardness of the second light-shielding layer 22 may be 0.4 kPa or more. The hardness of the second light-shielding layer 22 may be 0.45 kPa or more. The hardness of the second light-shielding layer 22 may be 0.52 kPa or less. The hardness of the second light-shielding layer 22 may be 0.5 kPa or less.

In this case, when pattern inspection is performed after patterning the light-shielding film 20, the frequency of detection of pseudo defects may be effectively reduced, and the amount of generation of particles generated from the patterned light-shielding film can be reduced.

The reflectance of the surface of the light-shielding film 20 with respect to light having a wavelength of 350 nm may be 25% or more and 45% or less. The reflectance may be 27% or more. The reflectance may be 30% or more. The reflectance may be 40% or less. In this case, it is possible to effectively lower the frequency of detection of pseudo defects when performing defect inspection on the surface of the light-shielding film.

In the defect inspector for the blank mask, the wavelength value of the inspection light may be applied within a range of 350 nm or more and 400 nm or less and a range of 480 nm or more and 550 nm or less. According to an embodiment, it is possible to control the reflectance characteristics of the light-shielding film 20 with respect to all light in the wavelength range. Therefore, reducing the degree to which the intensity of the reflected light affects the accuracy of the defect inspection during defect inspection is possible.

The reflectance of the surface of the light-shielding film 20 with respect to light having a wavelength of 350 nm or more and 400 nm or less may be 25% or more and 50% or less. The reflectance may be 28% or more. The reflectance may be 30% or more. The reflectance may be 45% or less. The reflectance may be 40% or less.

The reflectance of the surface of the light-shielding film 20 with respect to light having a wavelength of 480 nm or more and 550 nm or less may be 30% or more and 50% or less. The reflectance may be 35% or more. The reflectance may be 38% or more. The reflectance may be 45% or less. The reflectance may be 42% or less.

In this case, it is possible to suppress a decrease in the accuracy of defect inspection due to a flare phenomenon during defect inspection of the light-shielding film, and to effectively lower the frequency of detection of pseudo defects.

The hardness value of the second light-shielding layer 22 may be 0.15 times or more and 0.55 times or less the hardness value of the first light-shielding layer 21.

In the embodiment, a light-shielding film having a multilayer structure may be applied, and a ratio of the hardness value of the second light-shielding layer 22 to the hardness value of the first light-shielding layer 21 in the light-shielding film may be controlled. Therefore, the durability of the upper corner portion of the patterned light-shielding film 25 is further improved and etching rate ratios of the first light-shielding layer 21 and the second light-shielding layer 2 are adjusted using an etching gas, and thus it is possible to more precisely control the shape of the patterned light-shielding film.

The hardness value of the second light-shielding layer 22 is 0.15 times or more and 0.55 times or less than the hardness value of the first light-shielding layer 21. The hardness value of the second light-shielding layer 22 may be 0.2 times or more than that of the first light-shielding layer 21. The hardness value of the second light-shielding layer 22 may be 0.3 times or more than that of the first light-shielding layer 21. The hardness value of the second light-shielding layer 22 may be 0.5 times or less than that of the first light-shielding layer 21. The hardness value of the second light-shielding layer 22 may be less than or equal to 0.4 times the hardness value of the first light-shielding layer 21. In this case, the amount of particles generated from the patterned light-shielding film can be reduced. In addition, it is possible to effectively prevent a step from being generated on the side surface of the patterned light-shielding film.

The hardness of the first light-shielding layer 21 may be 1 kPa or more and 3 kPa or less. The hardness of the first light-shielding layer 21 may be 1.1 kPa or more. The hardness of the first light-shielding layer 21 may be 1.3 kPa or more. The hardness of the first light-shielding layer 21 may be 2.5 kPa or less. In this case, the first light-shielding layer 21 may have stable durability. In addition, during dry etching, the etching rate of the first light-shielding layer 21 is adjusted to have a relatively high value compared to the second light-shielding layer 22, so that the side surface of the patterned light-shielding film may be formed substantially perpendicular to the surface of the light-transmitting substrate through dry etching.

In an embodiment, a Young's modulus value and a Young's modulus value ratio of the second light-shielding layer 22 and the first light-shielding layer 21 may be controlled. Therefore, it is possible to effectively prevent damage to the light-shielding film 20 in an environment where an external force is applied to the surface of the light-shielding film 20, including a cleaning process.

The Young's modulus values of the second light-shielding layer 22 and the first light-shielding layer 21 may be adjusted by controlling not only the composition of each light-shielding layer but also the composition of atmospheric gas in a chamber when forming each light-shielding layer, thermal processing, and cooling conditions, etc.

A method of measuring the Young's modulus value of the first light-shielding layer 21 and the second light-shielding layer 22 may be measured by applying the same device as the device applied in the above-described method of measuring the hardness value.

The Young's modulus value of the second light-shielding layer 22 may be 1.0 kPa or more. The Young's modulus value of the second light-shielding layer 22 may be 1.2 kPa or more. The Young's modulus value of the second light-shielding layer 22 may be 2.3 kPa or more. The Young's modulus value of the second light-shielding layer 22 may be 4.2 kPa or less. The Young's modulus value of the second light-shielding layer 22 may be 3.7 kPa or less. The Young's modulus value of the second light-shielding layer 22 may be 3.5 kPa or less. In this case, it is possible to effectively prevent the second light-shielding layer 22 from being damaged by a cleaning process or the like while preventing the etching rate of the second light-shielding layer 22 from being excessively slowed by dry etching.

The Young's modulus value of the first light-shielding layer 21 may be 7 kPa or more and 13 kPa or less. The Young's modulus value of the first light-shielding layer 21 may be 8 kPa or more. The Young's modulus value of the first light-shielding layer 21 may be 12 kPa or less. The Young's modulus value of the first light-shielding layer 21 may be 11.8 kPa or less. In this case, when the light-shielding film 20 is dry-etched, the side surface of the first light-shielding layer 21 may be substantially perpendicular to the surface of the light-transmitting substrate 10, and the durability of the first light-shielding layer 21 may be stably controlled.

The Young's modulus value of the second light-shielding layer 22 may be 0.15 times or more and 0.55 times or less the Young's modulus value of the first light-shielding layer 21. The Young's modulus value of the second light-shielding layer 22 may be 0.20 times or more the Young's modulus value of the first light-shielding layer 21. The Young's modulus value of the second light-shielding layer 22 may be 0.23 times or more the Young's modulus value of the first light-shielding layer 21. The Young's modulus value of the second light-shielding layer 22 may be 0.45 times or less the Young's modulus value of the first light-shielding layer 21. The Young's modulus value of the second light-shielding layer 22 may be 0.42 times or less the Young's modulus value of the first light-shielding layer 21. In this case, it is possible to reduce the number of particles generated on the surface portion of the light-shielding film 20 in an environment where an external force is applied, including a cleaning process.

A full-off force, adhesion energy, etc., are also obtained by the measurement using an AFM. The full-off force and/or adhesion energy measured at 16 different positions have a small deviation in the all measured values, which means that the physical properties of the light-shielding film 20 are uniform throughout the measurement positions.

The standard deviation of adhesion energy measured at 16 different positions of the second light-shielding layer 22 (each position is preferably applied at least 1 cm apart from each other) may be 8% or less, may be 6% or less, or may be 5% or less. The standard deviation may be 0.001% or more of the average value of the adhesion energy. The entirety of the blank mask 100 or the photomask having these characteristics may have an effect of uniformly reducing particle formation even if a fine pattern is formed.

The adhesion energy of the second light-shielding layer 22 may be 0.25 fJ or more. The adhesion energy of the second light-shielding layer 22 may be 0.30 fJ or more. The adhesion energy of the second light-shielding layer 22 may be 0.4 fJ or less.

The adhesion energy of the second light-shielding layer 22 may be greater than that of the first light-shielding layer 21 by 0.10 fJ or more. The adhesion energy of the second light-shielding layer 22 may be greater than that of the first light-shielding layer 21 by 0.15 fJ or less.

The standard deviation of the pull-off force measured at 16 different positions of the second light-shielding layer 22 may be 5% or less, 3% or less, or 2% or less of the average of the pull-off force. The standard deviation may be 0.001% or more of the average of the pull-off force. The entirety of the blank mask 100 or the photomask having these characteristics may have an effect of uniformly reducing scratch formation.

The pull-off force of the second light-shielding layer 22 may be 4.0 nN or more. The pull-off force of the second light-shielding layer 22 may be 4.1 nN or more. The pull-off force of the second light-shielding layer 22 may be 4.8 nN or less.

The pull-off force of the second light-shielding layer 22 may be greater than that of the first light-shielding layer 21 by 0.6 nN or more. The pull-off force of the second light-shielding layer 22 may be greater than that of the first light-shielding layer 21 by 1.2 nN or less.

The transmittance and optical density of the light-shielding film 20 are measured through a spectroscopic ellipsometer. The reflectance of the light-shielding film 20 may be measured using, for example, the MG-Pro model manufactured by Nano-View Co. Ltd.

The transmittance of the light-shielding film 20 with respect to light having a wavelength of 193 nm may be 1% or more. The transmittance may be 1.33% or more. The transmittance may be 1.38% or more. The transmittance may be 1.4% or more. The transmittance may be 1.6 or less.

An optical density of the light-shielding film 20 with respect to light having a wavelength of 193 nm may be 2.0 or less. The optical density may be 1.87 or less. The optical density may be 1.8 or more. The optical density may be 1.83 or more.

In this case, the light-shielding film 20 together with the phase shift film may effectively block the exposure light.

### Layer Structure of Light-Shielding Film

The light-shielding film 20 may include a first light-shielding layer 21 and a second light-shielding layer 22 disposed on the first light-shielding layer 21. The second light-shielding layer 22 may be formed on and in contact with the first light-shielding layer 21. Another thin film may be disposed between the second light-shielding layer 22 and the first light-shielding layer 21.

The first light-shielding layer 21 and the second light-shielding layer 22 may have a thickness ratio of 1:0.02 to 0.25. The first light-shielding layer 21 and the second light-shielding layer 22 may have a thickness ratio of 1:0.04 to 0.18. The light-shielding film 20, including both the first light-shielding layer 21 and the second light-shielding layer 22 may have characteristics of suppressing the generation of particles and reducing scratches while satisfying desired conditions such as transmittance, optical density, etc.

The light-shielding film 20 may have a thickness of 30 to 80 nm. The light-shielding film 20 may have a thickness of 40 to 70 nm. In this case, the effect of reducing particle formation may be more excellent.

The thickness or thickness ratio may be confirmed by layer division confirmed by a micrograph of a cross section, and any method that can confirm the thickness can be applied without limitation.

A film thickness of the first light-shielding layer 21 may be 250 to 650 Å. The film thickness of the first light-shielding layer 21 may be 350 to 600 Å. The film thickness of the first light-shielding layer 21 may be 400 to 550 Å. In this case, the first light-shielding layer 21 may help the light-shielding film 20 to effectively block exposure light.

A film thickness of the second light-shielding layer 22 may be 30 to 200 Å. The film thickness of the second light-shielding layer 22 may be 30 to 100 Å. The film thickness of the second light-shielding layer 22 may be 40 to 80 Å. In this case, the light-shielding film 20 may have a surface reflectance value in a predetermined range in the embodiment, and it may help a side surface profile of the patterned light-shielding film formed when the light-shielding film 20 is patterned, to be more precisely controlled.

### Composition of Light-Shielding Film

In an embodiment, the content of each element of each layer included in the light-shielding film 20 may be controlled. Therefore, while imparting a light-shielding property to the light-shielding film 20, it is possible to help the accuracy of inspection to be improved when inspecting defects of the light-shielding film 20 or the patterned light-shielding film. In addition, it can help reduce the amount of particles generated from the patterning process of the light-shielding film 20 or the patterned light-shielding film that has been patterned, by affecting the mechanical properties of each layer in the light-shielding film 20.

However, the mechanical properties of each layer in the light-shielding film 20 may be affected not only by the composition of each layer, but also by the density of each layer, the degree of crystallization of elements included in each layer, arrangement of elements, and the like. In the embodiment, it is possible to adjust the mechanical properties of each layer in the light-shielding film 20 by controlling sputtering power applied in a sputtering process of each layer, the content of an inert gas contained in an atmospheric gas, the composition of a reactive gas, etc. while controlling the composition of each layer in the light-shielding film 20. Specific details will be described below.

The second light-shielding layer 22 may include at least one of a transition metal, oxygen, and nitrogen. The second light-shielding layer 22 may contain the transition metal at 35 at % or more. The second light-shielding layer 22 may contain the transition metal at 40 at % or more. The second light-shielding layer 22 may contain the transition metal at 45 at % or more. The second light-shielding layer 22 may contain the transition metal at 50 at % or more. The second light-shielding layer 22 may contain the transition metal at 75 at % or less. The second light-shielding layer 22 may contain the transition metal at 70 at % or less. The second light-shielding layer 22 may contain the transition metal at 65 at % or less. The second light-shielding layer 22 may contain the transition metal at 60 at % or less.

The content of the element corresponding to oxygen or nitrogen in the second light-shielding layer 22 may be 15 at % or more. The content may be 25 at % or more. The content may be 70 at % or less. The content may be 65 at % or less. The content may be 60 at % or less.

The second light-shielding layer 22 may contain 10 at % or more oxygen. The second light-shielding layer 22 may contain 15 at % or more oxygen. The second light-shielding layer 22 may contain 20 at % or more oxygen. The second light-shielding layer 22 may contain 40 at % or less oxygen. The second light-shielding layer 22 may contain 35 at % or less oxygen. The second light-shielding layer 22 may contain 30 at % or less oxygen.

The second light-shielding layer 22 may contain 5 at % or more nitrogen. The second light-shielding layer 22 may contain 10 at % or more nitrogen. The second light-shielding layer 22 may contain 30 at % or less nitrogen. The second light-shielding layer 22 may contain 25 at % or less nitrogen. The second light-shielding layer 22 may contain 22 at % or less nitrogen.

The second light-shielding layer 22 may contain 1 at % or more carbon. The second light-shielding layer 22 may contain 3 at % or more carbon. The second light-shielding layer 22 may contain 25 at % or less carbon. The second light-shielding layer 22 may contain 20 at % or less carbon. The second light-shielding layer 22 may contain 15 at % or less carbon.

In this case, this may help the light-shielding film 20 to have a surface reflectance characteristic that is easy to perform defect inspection. In addition, it may help the durability of the surface portion of the light-shielding film 20 to be further improved.

The first light-shielding layer 21 may include a transition metal, oxygen, and nitrogen. The first light-shielding layer 21 may contain the transition metal at 20 at % or more. The first light-shielding layer 21 may contain the transition metal at 25 at % or more. The first light-shielding layer 21 may contain the transition metal at 30 at % or more. The first light-shielding layer 21 may contain the transition metal at 45 at % or less. The first light-shielding layer 21 may contain the transition metal at 40 at % or less. The first light-shielding layer 21 may contain the transition metal at 35 at % or less.

The sum of the oxygen content and the nitrogen content of the first light-shielding layer 21 may be 22 at % or more. The sum of the oxygen content and the nitrogen content of the first light-shielding layer 21 may be 30 at % or more. The sum of the oxygen content and the nitrogen content of the first light-shielding layer 21 may be 35 at % or more. The sum of the oxygen content and the nitrogen content of the first light-shielding layer 21 may be 75 at % or less. The sum of the oxygen content and the nitrogen content of the first light-shielding layer 21 may be 65 at % or less.

The first light-shielding layer 21 may contain 20 at % or more oxygen. The first light-shielding layer 21 may contain 25 at % or more oxygen. The first light-shielding layer 21 may contain 30 at % or more oxygen. The first light-shielding layer 21 may contain 55 at % or less oxygen. The first light-shielding layer 21 may contain 50 at % or less oxygen. The first light-shielding layer 21 may contain 45 at % or less oxygen.

The first light-shielding layer 21 may contain 2 at % or more nitrogen. The first light-shielding layer 21 may contain 5 at % or more nitrogen. The first light-shielding layer 21 may contain 20 at % or less nitrogen. The first light-shielding layer 21 may contain 15 at % or less nitrogen.

The first light-shielding layer 21 may contain 5 at % or more carbon. The first light-shielding layer 21 may contain 10 at % or more carbon. The first light-shielding layer 21 may contain 30 at % or less carbon. The first light-shielding layer 21 may contain 25 at % or less carbon.

In this case, the first light-shielding layer 21 may help the light-shielding film 20 to have excellent quenching characteristics. In addition, during dry etching, the first light-shielding layer 21 may exhibit a relatively high etching rate compared to the second light-shielding layer 22.

A difference between the content value of each element included in the second light-shielding layer 22 and the content value of each element included in the first light-shielding layer 21 may be controlled. Specifically, the first light-shielding layer 21 and the second light-shielding layer 22 may be disposed in contact with each other. In this case, a difference in physical properties, such as surface energy between the first light-shielding layer 21 and the second light-shielding layer 22 may be adjusted by controlling the composition between the first light-shielding layer 21 and the second light-shielding layer 22, especially, a difference in the transition metal content. Therefore, a bond between atoms on the surface of the first light-shielding layer 21 and atoms on the surface of the second light-shielding layer 22, which are positioned at an interface between the first light-shielding layer 21 and the second light-shielding layer 22, can be easily established, and the occurrence of defects due to insufficient adhesion between the first light-shielding layer 21 and the second light-shielding layer 22 can be effectively suppressed.

An absolute value of a value obtained by subtracting the transition metal content of the first light-shielding layer 21 from the transition metal content of the second light-shielding layer 22 may be 30 at % or less. The absolute value may be 25 at % or less. The absolute value may be 20 at % or less. The absolute value may be 7 at % or more. The absolute value may be 10 at % or more. The absolute value may be 12 at % or more. In this case, the adhesion formed between the first light-shielding layer 21 and the second light-shielding layer 22 can be improved.

The transition metal may include at least one of Cr, Ta, Ti, and Hf. The transition metal may be Cr.

### Other Thin Films

FIG. 3 is a conceptual diagram illustrating a blank mask according to another embodiment disclosed herein. The blank mask, according to the embodiment, will be described with reference to FIG. 3.

The blank mask 100, according to another embodiment of the present specification, includes a light-transmitting substrate 10, a phase shift film 30 disposed on the light-transmitting substrate 10, and a light-shielding film 20 disposed on the phase shift film 30.

The phase shift film 30 includes a transition metal and silicon.

Description of the light-shielding film 20 will be omitted because the description overlaps the previous description.

The phase shift film 30 may be positioned between the light-transmitting substrate 10 and the light-shielding film 20. The phase shift film 30 is a thin film that attenuates the light intensity of exposure light passing through the phase shift film 30 and substantially suppresses diffracted light generated at the edge of a pattern by adjusting a phase difference.

The phase shift film 30 may have a phase difference of 170 to 190° with respect to light having a wavelength of 193 nm. The phase shift film 30 may have a phase difference of 175 to 185° with respect to light having a wavelength of 193 nm. The phase shift film 30 may have a transmittance of 3 to 10% with respect to light having a wavelength of 193 nm. The phase shift film 30 may have a transmittance of 4 to 8% with respect to light having a wavelength of 193 nm. In this case, the resolution of a photomask including the phase shift film 30 can be improved.

The phase shift film 30 may include a transition metal and silicon. The phase shift film 30 may include a transition metal, silicon, oxygen, and nitrogen. The transition metal may be molybdenum.

Descriptions of the physical properties and compositions of the light-transmitting substrate 10 and the light-shielding film 20 will be omitted because the descriptions overlap those described above.

A hard mask (not shown) may be positioned on the light-shielding film 20. The hard mask may function as an etching mask film when performing pattern-etching on the light-shielding film 20. The hard mask may include silicon, nitrogen, and oxygen.

### Photomask

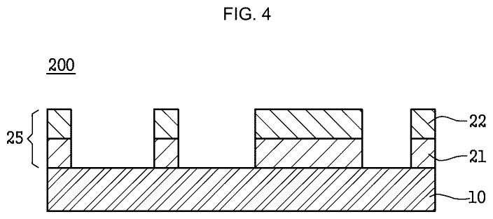

FIG. 4 is a conceptual diagram illustrating a photomask according to still another embodiment disclosed herein. The photomask, according to the embodiment, will be described with reference to FIG. 4.

The photomask 200, according to still another embodiment of the present specification, includes a light-transmitting substrate 10 and a patterned light-shielding film 25 disposed on the light-transmitting substrate 10.

The patterned light-shielding film 25 includes a first light-shielding layer 21 and a second light-shielding layer 22 disposed on the first light-shielding layer 21.

The patterned light-shielding film 25 includes at least one of a transition metal, oxygen, and nitrogen.

The second light-shielding layer 22 includes at least one of a transition metal, oxygen, and nitrogen.

A reflectance of the upper surface of the patterned light-shielding film 25 with respect to light having a wavelength of 193 nm is 20% or more and 40% or less.

A hardness value of the second light-shielding layer 22 is 0.3 kPa or more and 0.55 kPa or less.

The patterned light-shielding film 25 may be formed by patterning the light-shielding film 20 of the blank mask 100 described above.

Description of the physical properties, composition, and structure of the patterned light-shielding film 25 will be omitted because the descriptions overlap the description of the light-shielding film 20 of the blank mask 100.

### Method of Manufacturing Light-Shielding Film

A method of manufacturing a blank mask according to an embodiment of the present specification may include a preparation operation of installing a substrate and a sputtering target in a sputtering chamber.

The method of manufacturing the blank mask, according to the embodiment of the present specification, may include a film-forming operation of injecting an atmospheric gas into the sputtering chamber and applying power to the sputtering target to form a light-shielding film on the substrate.

The film-forming operation may include a first light-shielding layer forming operation of forming a first light-shielding layer on a light-transmitting substrate and a second light-shielding layer forming operation of forming a second light-shielding layer on the first light-shielding layer.

The method of manufacturing the blank mask according to the embodiment of the present specification may include a thermal processing operation of performing thermal processing in an atmosphere of 150° C. or more and 300° C. or less for 5 minutes or more and 30 minutes or less.

The method of manufacturing the blank mask according to the embodiment of the present specification may include a cooling operation of cooling the light-shielding film that has been subjected to the thermal processing operation.

The method of manufacturing the blank mask according to the embodiment of the present specification may include a stabilizing operation of stabilizing the blank mask that has subjected to the cooling operation in an atmosphere of 10° C. or more and 60° C. or less.

In the preparation operation, a target may be selected in order that the light-shielding film is formed in consideration of the composition of the light-shielding film. As the sputtering target, one target containing a transition metal may be applied. As the sputtering target, two or more targets, including one target containing a transition metal, may be applied. The target containing the transition metal may contain the transition metal at 90 at % or more. The target containing the transition metal may contain the transition metal at 95 at % or more. The target containing the transition metal may contain the transition metal at 99 at %.

The transition metal may include at least one of Cr, Ta, Ti, and Hf. The transition metal may include Cr.

As the substrate disposed in the sputtering chamber, the light-transmitting substrate or a phase-shifting film deposited on the light-transmitting substrate may be applied.

A magnet may be disposed in the sputtering chamber in the preparation operation. The magnet may be disposed on a surface opposite to one surface on which sputtering is performed using the sputtering target.

In the light-shielding film forming operation, different film-forming process conditions may be applied when forming a film for each layer included in the light-shielding film. Considering optical properties such as reflectance, optical density, and mechanical properties of the light-shielding film, various process conditions such as atmospheric gas composition, power applied to the sputtering target, and film formation time may be different applied to each layer.

The atmospheric gas may include an inert gas, a reactive gas, and a sputtering gas. The inert gas is a gas that does not contain an element constituting the formed thin film. The reactive gas is a gas containing an element constituting the formed thin film. The sputtering gas is a gas that is ionized in a plasma atmosphere and collides with a target.

The inert gas may include helium.

The reactive gas may include a gas containing nitrogen element. The gas including the nitrogen element may be, for example, N₂, NO, NO₂, N₂O, N₂O₃, N₂O₄, N₂O₅, or the like. The reactive gas may include a gas containing elemental oxygen. The gas, including the oxygen element, may be, for example, O₂, CO₂, or the like. The reactive gas may include a gas containing nitrogen element and a gas containing oxygen element. The reactive gas may include a gas containing both the nitrogen element and the oxygen element. The gas including both the nitrogen element and the oxygen element may be, for example, NO, NO₂, N₂O, N₂O₃, N₂O₄, N₂O₅, or the like.

The sputtering gas may be an Ar gas.

A power source for applying power to the sputtering target may use a DC power source or an RF power source.

In the first light-shielding layer forming operation, the power applied to the sputtering target may be applied in a range of 1.5 KW or more and 2.5 KW or less. In the first light-shielding layer forming operation, power applied to the sputtering target may be applied in a range of 1.6 KW or more and 2 KW or less. In this case, during dry etching, mechanical properties of the first light-shielding layer may be adjusted to help the first light-shielding layer to have a stable etching rate during dry etching.

In the first light-shielding layer forming operation, the atmospheric gas injected into the sputtering chamber may include an inert gas together with the sputtering gas. During sputtering, physical properties such as the density, hardness, etc. of the thin film to be formed may be controlled within a predetermined range in the embodiment by controlling the content of the inert gas in the atmospheric gas.

In the atmospheric gas, the content (vol %) of the inert gas may be one or more times the content (vol %) of the sputtering gas. The content (vol %) of the inert gas may be 1.2 times or more the content (vol %) of the sputtering gas. The content (vol %) of the inert gas may be 1.5 times or more the content (vol %) of the sputtering gas. The content (vol %) of the inert gas may be three times or less the content (vol %) of the sputtering gas. The content (vol %) of the inert gas may be 2.5 times or less the content (vol %) of the sputtering gas. The content (vol %) of the inert gas may be 2.2 times or less the content (vol %) of the sputtering gas.

The content of the inert gas based on the total atmospheric gas may be 20 vol % or more. The content may be 25 vol % or more. The content may be 30 vol % or more. The content may be 50 vol % or less. The content may be 45 vol % or less. The content may be 40 vol % or less.

In this case, it may help the hardness value or the like of the first light-shielding layer to be adjusted within a predetermined range in the embodiment.

A ratio of the oxygen content (at %) to the nitrogen content (at %) included in the reactive gas may be 1.5 or more and 4 or less. The ratio of the oxygen content (at %) to the nitrogen content (at %) included in the reactive gas may be 2 or more and 3 or less. The ratio of the oxygen content (at %) to the nitrogen content (at %) included in the reactive gas may be 2.2 or more and 2.7 or less.

In this case, it may help the amount of particles generated from the first light-shielding layer to be reduced, and during dry etching, the etching rate of the first light-shielding layer compared to the second light-shielding layer can be improved.

A film-forming time of the first light-shielding layer may be 200 seconds or longer and 300 seconds or shorter. The film-forming time of the first light-shielding layer may be 210 seconds or longer and 240 seconds or shorter. In this case, the first light-shielding layer may help the light-shielding film to have sufficient quenching characteristics.

After the first light-shielding layer is formed, the supply of power and the atmospheric gas to the sputtering chamber may be stopped for 5 seconds or longer and 10 seconds or shorter, and the power and the atmospheric gas may be supplied again during the second light-shielding layer forming operation.

In the second light-shielding layer forming operation, power applied to the sputtering target may be applied in a range of 1 kW or more to 2 KW or less. In the second light-shielding layer forming operation, power applied to the sputtering target may be applied in a range of 1.2 KW or more and 1.7 kW or less. In this case, it may help the hardness, Young's modulus value, and the like of the second light-shielding layer to be controlled within a predetermined range in the embodiment.

In the second light-shielding layer forming operation, a ratio of the content (vol %) of the reactive gas to the content (vol %) of the sputtering gas in the atmosphere gas may be 0.3 or more and 0.8 or less. The content (volume %) ratio may be 0.4 or more and 0.6 or less.

In the second light-shielding layer forming operation, a ratio of an oxygen content (at %) to a nitrogen content (at %) included in the reactive gas may be 0.3 or less. The ratio of the oxygen content (at %) to the nitrogen content (at %) included in the reactive gas may be 0.1 or less. The ratio of the oxygen content (at %) to the nitrogen content (at %) included in the reactive gas may be 0.001 or more.

In this case, it may help improve the durability of the upper portion of the patterned light-shielding film formed by patterning the light-shielding film, and it is possible to improve the accuracy of inspection during defect inspection of the light-shielding film or the patterned light-shielding film formed by patterning the light-shielding film.

The film-forming time of the second light-shielding layer may be 10 seconds or longer and 30 seconds or shorter. The film-forming time of the second light-shielding layer may be 15 seconds or longer and 25 seconds or shorter. In this case, it may help enable more sophisticated light-shielding layer patterning during dry etching.

A ratio of the reactive gas content (vol %) applied in the second light-shielding layer formation operation to the reactive gas content (vol %) applied in the first light-shielding layer formation operation may be 0.7 or more and 1.1 or less. The ratio may be 0.8 or more and 1.05 or less. The ratio may be 0.85 or more and 0.95 or less. In this case, it may be easier to control the hardness and Young's modulus ratio of the first light-shielding layer and the second light-shielding layer.

In the thermal processing operation, thermal processing may be performed on the light-shielding film subjected to the film-forming operation. Specifically, the substrate on which the light-shielding film has been formed may be disposed in a thermal processing chamber, and then thermal processing may be performed.

By heat-treating the light-shielding film, stress generated in the light-shielding film may be removed, and the density of the light-shielding film may be further improved. When thermal processing is performed on the light-shielding film, the transition metal included in the light-shielding film may be subjected to recovery and recrystallization, and the stress generated in the light-shielding film may be effectively removed. However, in the thermal processing operation, when process conditions such as thermal processing temperature and time are not controlled, grain growth may occur in the light-shielding film, and the arrangement of transition metal atoms in the light-shielding film may be significantly modified compared to before thermal processing, due to grains composed of transition metals that are not size-controlled. This may affect the mechanical properties, such as the density and hardness of the light-shielding film, and may also affect the roughness characteristics of the surface of the light-shielding film, thereby causing a change in reflectance characteristics of the light-shielding film.

In the embodiment, the thermal processing time and temperature may be controlled in the thermal processing operation, and in the cooling operation to be described below, each layer in the light-shielding film may have predetermined mechanical properties in the embodiment while effectively removing internal stress generated in the light-shielding film by controlling the cooling rate, cooling time, and atmospheric gas during cooling, the internal stress formed in the light-shielding film, and the reflectance value of the surface of the light-shielding film may have an appropriate value for defect inspection.

The thermal processing operation may be performed at 150 to 330° C. The thermal processing operation may be performed at 180 to 280° C.

The thermal processing operation may be performed for 5 to 30 minutes. The thermal processing operation may be performed for 10 to 20 minutes. The time is the time excluding the temperature increase time.

In this case, it may help effectively remove the internal stress generated in the light-shielding film, and may help suppress the excessive growth of transition metal particles due to thermal processing.

In the cooling operation, the light-shielding film that has been subjected to the thermal processing may be cooled. The blank mask may be cooled by arranging a cooling plate adjusted to a predetermined cooling temperature in the embodiment, on a side facing the substrate, of the blank mask on which the thermal processing operation has been completely performed. In the cooling operation, the cooling rate of the blank mask may be controlled by adjusting a gap between the blank mask and the cooling plate and applying process conditions such as introducing atmospheric gas.

The blank mask may be subjected to the cooling operation within 2 minutes after the thermal processing operation has been completed. In this case, it is possible to effectively prevent the growth of transition metal particles due to residual heat in the light-shielding film.

The cooling rate of the blank mask can be controlled by installing pins having an adjusted length on the cooling plate at each corner, and placing a blank mask on the pins so that the substrate faces the cooling plate.

A pin having a controlled length may be installed on each corner of a cooling plate, and the blank mask may be disposed on the pin in such a manner that the substrate faces the cooling plate, thereby controlling the cooling rate of the blank mask.

In addition to the cooling method by the cooling plate, the blank mask may be cooled by injecting an inert gas into a space where the cooling operation is performed. In this case, it is possible to more effectively remove residual heat from the light-shielding film side of the blank mask, in which cooling efficiency by the cooling plate is somewhat lower.

The inert gas may be, for example, helium.

In the cooling operation, the cooling temperature applied to the cooling plate may be 10 to 30° C. The cooling temperature may be 15 to 25° C.

In the cooling operation, a separation distance between the blank mask and the cooling plate may be 0.01 to 30 mm. The separation distance may be 0.05 to 5 mm. The separation distance may be 0.1 to 2 mm.

In the cooling operation, the cooling rate of the blank mask may be 30 to 80° C./min. The cooling rate may be 35 to 75° C./min. The cooling rate may be 40 to 70° C./min.

In this case, by suppressing the grain growth of the transition metal due to the heat remaining in the light-shielding film after thermal processing, it may help each layer in the light-shielding film to have a hardness value in a predetermined range in the embodiment and help the surface of the light-shielding film to have a reflectance characteristic suitable for defect inspection.

In the stabilization operation, the blank mask that has been subjected to the cooling operation may be stabilized. Therefore, it is possible to prevent damage to the blank mask due to a sudden temperature change.

There may be various methods for stabilizing the blank mask that has been subjected to the cooling operation. As an example, after the blank mask that has been subjected to the cooling operation may be separated from the cooling plate, the blank mask may be left in an atmosphere at room temperature for a predetermined time. As another example, after the blank mask that has been subjected to the cooling operation may be separated from the cooling plate, the blank mask may be stabilized in an atmosphere of 15° C. or more and 30° C. or less for 30 minutes or more and 200 minutes or less. At this time, the blank mask may be rotated at a speed of 20 rpm or more and 50 rpm or less. As another example, a gas that does not react with the blank mask may be sprayed to the blank mask that has been subjected to the cooling operation at a flow rate of 5 L/min or more and 10 L/min or less for a period of 1 minute or more and 5 minutes or less. At this time, the gas that does not react with the blank mask may have a temperature of 20° C. or higher and 40° C. or lower.

### Method of Manufacturing Semiconductor Device

A method of manufacturing a semiconductor device according to another embodiment of the present specification includes a preparation operation of arranging a light source, a photomask, and a semiconductor wafer coated with a resist film, an exposure operation of selectively transmitting and emitting light incident from the light source through the photomask on the semiconductor wafer, and a developing operation of developing a pattern on the semiconductor wafer.

The photomask includes a light-transmitting substrate and a patterned light-shielding film disposed on the light-transmitting substrate.

The patterned light-shielding film includes a first light-shielding layer and a second light-shielding layer disposed on the first light-shielding layer.

The patterned light-shielding film 25 includes at least one of a transition metal, oxygen, and nitrogen.

The second light-shielding layer 22 includes at least one of a transition metal, oxygen, and nitrogen.

A reflectance of the upper surface of the patterned light-shielding film with respect to light having a wavelength of 193 nm is 20% or more and 30% or less.

A hardness value of the second light-shielding layer is 0.3 kPa or more and 0.55 kPa or less.

In the preparation operation, the light source is a device capable of generating exposure light of a short wavelength. The exposure light may be light having a wavelength of 200 nm or less. The exposure light may be ArF light having a wavelength of 193 nm.

A lens may be further disposed between the photomask and the semiconductor wafer. The lens has the function of reducing the shape of the circuit pattern on the photomask and transferring the reduced shape of the circuit pattern onto the semiconductor wafer. The lens is not limited as long as it can be generally applied to an ArF semiconductor wafer exposure process. For example, a lens made of calcium fluoride (CaF2) may be applied as the lens.

In the exposure operation, the exposure light may be selectively transmitted on the semiconductor wafer through the photomask. In this case, chemical transformation may occur in a portion of the resist film to which the exposure light is incident.

In the developing operation, the semiconductor wafer that has been subjected to the exposure operation may be treated with a developing solution to develop a pattern on the semiconductor wafer. When the applied resist film is a positive resist, the portion of the resist film on which the exposure light is incident may be dissolved by the developing solution. When the applied resist film is a negative resist, a portion of the resist film on which exposure light is not incident may be dissolved by the developing solution. The resist film is formed into a resist pattern by treatment with the developing solution. A pattern may be formed on the semiconductor wafer using the resist pattern as the mask.

Description of the photomask is omitted because the description overlaps the previous content.

Hereinafter, specific examples will be described in more detail.

### Manufacturing Example: Manufacturing of Light-Shielding Film

Example 1: A substrate having a phase difference of about 180° with respect to light having a wavelength of 193 nm was prepared on a synthetic quartz light-transmitting substrate having a width of 6 inches, a length of 6 inches, and a thickness of 0.25 inches, and was applied to the manufacture of a light-shielding film.

The substrate was placed in a chamber of a DC sputtering device, and the T/S distance of a chromium target was 255 mm, and an angle between the substrate and the target was 25 degrees. The electric power applied when forming the first light-shielding layer was 1.85 KW, and the electric power applied when forming the second light-shielding layer was 1.5 kW.

As shown in Table 1, sputtering was performed by applying atmospheric gases while rotating the substrate, and the light-shielding film was formed by sequentially forming a first light-shielding layer and a second light-shielding layer.

The thermal processing was performed in the same manner at 200° C. for 15 minutes, and the light-shielding film that has been subjected to the thermal processing was cooled by applying dry air for 5 minutes in an atmosphere of 20° C.

Process conditions for each Example and Comparative Example are described in Table 1 below.

### Evaluation Example: Composition Evaluation

A transition metal element, specifically, chromium, content of each layer in the light-shielding film for each Example and Comparative Example was measured using XPS analysis. Specifically, a specimen was prepared by processing a blank mask for each Example and Comparative Example with a size of 15 mm in width and 15 mm in length. After the specimen was placed in a K-Alpha model measuring device manufactured by Thermo Scientific Corporation, an area of 4 mm in width and 2 mm in length located in the center of the specimen was etched to measure the chromium content of each layer. The measurement results for each Example and Comparative Example are shown in Table 2 below.

### Evaluation Example: Evaluation of Optical Properties

Using a spectroscopic ellipsometer, the transmittance and optical density of the light-shielding film of each Example and Comparative Example with respect to light having a wavelength of 193 nm were measured.

In addition, the surface reflectance of the light-shielding film according to the wavelength of the inspection light of Example 1 was measured using the spectroscopic ellipsometer. Specifically, while incrementing the inspection light wavelength from 190 nm in a unit of 1 nm, the surface reflectance of the light-shielding film of Example 1 according to each wavelength was measured. Thereafter, the measured reflectance values were regression-analyzed and plotted as a graph.

As the spectroscopic ellipsometer used to evaluate the optical properties, MG-Pro manufactured by Nano-View Co. Ltd. was used.

The measured values of the transmittance and optical density for each Example and Comparative Example are shown in Table 3 below.

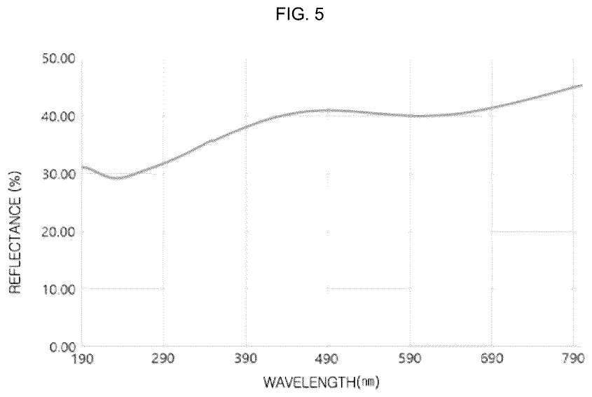

A graph obtained by measuring the surface reflectance of the light-shielding film according to the wavelength of the inspection light of Example 1 is shown in FIG. 5.

### Evaluation Example: Evaluation of Mechanical Properties

Hardness, Young's modulus, separation force, adhesive force, etc. were measured using an AFM. Using AFM equipment (equipment model XE-150) manufactured by Park Systems Corporation, cantilever model PPP-CONTSCR manufactured by Park Systems Corporation was applied to perform measurement at a scan rate of 0.5 Hz and a contact mode, and the adhesive force was measured at 16 points within the measurement target was measured to obtain an average value thereof, and the hardness or Young's modulus values obtained therefrom are shown in Table 3 below as the above hardness or Young's modulus values.

The measured data at 16 points in Example 2 are presented in Table 4. For a measuring tip applied during measurement, a Berkovich tip (Poisson's ratio of tip: 0.07) made of silicone was applied, and the hardness and Young's modulus measurement results were obtained by a program provided by the AFM equipment company by applying the Oliver and Pharr Model.

### Evaluation Example: Evaluation of Etching Characteristics

The thickness of the light-shielding film was measured by measuring a transmission electron microscope (TEM) image of the light-shielding film included in the specimens of Examples and Comparative Examples. The specimen was processed to have a size of 15 mm in width and 15 mm in length. The surface of the processed specimen was treated with a focused ion beam (FIB) using the Helios 5 HX DualBeam System of Thermo Fisher Scientific Inc., and placed in the JEM-2100F HR model equipment of JEOL Ltd. to measure the TEM image of the specimen. The thickness of the light-shielding film was calculated from the TEM image.

Thereafter, the etching time of the light-shielding film with respect to a chlorine-based gas was measured. As the chlorine-based gas, a gas containing 90 to 95 vol % of chlorine gas and 5 to 10 vol % of oxygen gas was applied. The etching rate of the light-shielding film with respect to the chlorine-based gas was calculated from the thickness of the light-shielding film and the etching time of the light-shielding film.

The etching rate measurement values for each Example and Comparative Example are shown in Table 3 below.

### Evaluation Example: Defect Evaluation

Whether a defect was formed on the surface of the light-shielding film of Comparative Examples 1 and 2 was measured using a defect inspector. Specifically, after applying the HF filter to the inspection equipment of M6641S model of Lasertec Corporation, images of the surface of the light-shielding film of Comparative Examples 1 and 2 were measured.

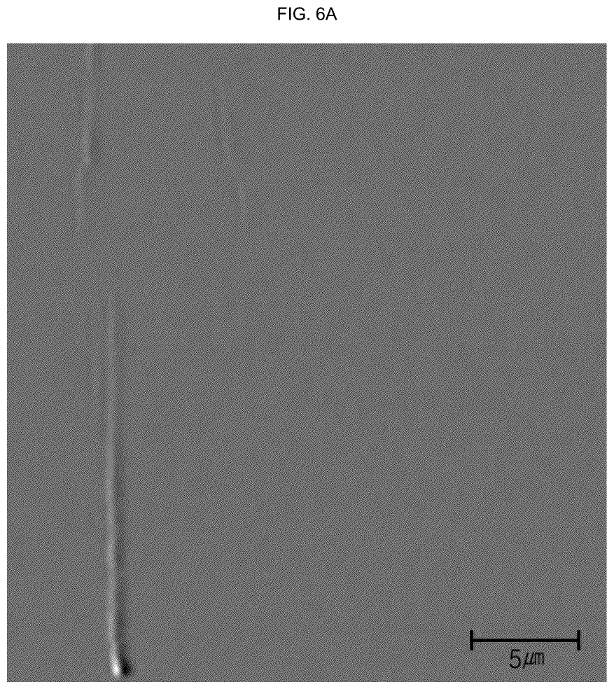

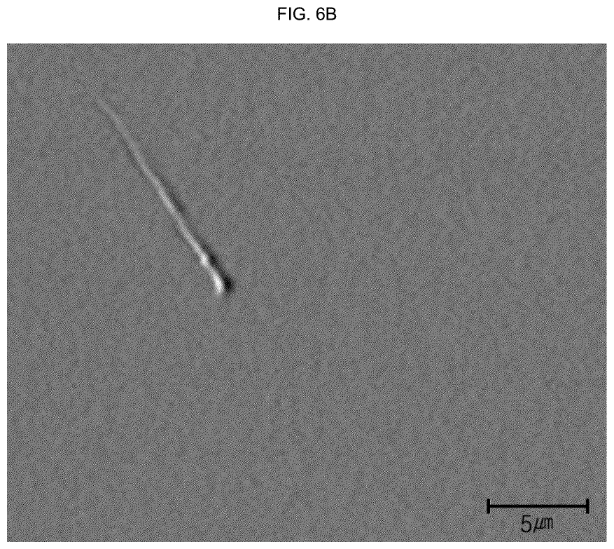

The light-shielding film surface images of Comparative Examples 1 and 2 are shown in FIGS. 6A and 6B, respectively.

TABLE 1

| | | Film- | atmospheric gas | | | | Reactive |
|---|---|---|---|---|---|---|---|
| | | formation | volume ratio | | | | gas |
| | Layer type | time (s) | Ar | N₂ | CO₂ | He | ratio |
| Example 1 | First light- | 230~300 | 21 | 11 | 32 | 36 | 1 |
| | shielding | | | | | | |
| | layer | | | | | | |
| | Second | 20~28 | 57 | 11 | 32 | 0 | |
| | light- | | | | | | |
| | shielding | | | | | | |
| | layer | | | | | | |
| Example 2 | First light- | 230~300 | 19 | 11 | 36 | 34 | 0.915 |
| | shielding | | | | | | |
| | layer | | | | | | |
| | Second | 20~28 | 57 | 11 | 32 | 0 | |
| | light- | | | | | | |
| | shielding | | | | | | |
| | layer | | | | | | |
| Example 3 | First light- | 230~300 | 17 | 24 | 49 | 30 | 0.811 |
| | shielding | | | | | | |
| | layer | | | | | | |
| | Second | 20~28 | 57 | 11 | 32 | 0 | |
| | light- | | | | | | |
| | shielding | | | | | | |
| | layer | | | | | | |
| Comparative | First light- | 230~300 | 21 | 11 | 32 | 36 | — |
| Example 1 | shielding | | | | | | |
| | layer First | | | | | | |
| | light- | | | | | | |
| | shielding | | | | | | |
| | layer | | | | | | |
| | Second | — | — | — | — | — | |
| | light- | | | | | | |
| | shielding | | | | | | |
| | layer | | | | | | |
| Comparative | First light- | 230~300 | 21 | 11 | 32 | 36 | 1.302 |
| Example 2 | shielding | | | | | | |
| | layer | | | | | | |
| | Second | 20~28 | 44 | 56 | 0 | 0 | |
| | light- | | | | | | |
| | shielding | | | | | | |
| | layer | | | | | | |
| Comparative | First light- | 230~300 | 19 | 11 | 36 | 34 | 0.426 |
| Example 3 | shielding | | | | | | |
| | layer | | | | | | |
| | Second | 20~28 | 80 | 20 | 0 | 0 | |
| | light- | | | | | | |
| | shielding | | | | | | |
| | layer | | | | | | |

Ratio (volume ratio) of reactive gas applied when forming the second light-shielding layer based on the reactive gas applied when forming the first light-shielding layer

TABLE 2

| | | Cr (at %) |
|---|---|---|
| Example 1 | First light- | 38 |
| | shielding layer | |
| | Second light- | 55 |
| | shielding layer | |
| Example 2 | First light- | 25 |
| | shielding layer | |
| | Second light- | 40 |
| | shielding layer | |
| Example 3 | First light- | 50 |
| | shielding layer | |
| | Second light- | 65 |
| | shielding layer | |
| Comparative | First light- | 15 |
| Example 1 | shielding layer | |
| | Second light- | 30 |
| | shielding layer | |
| Comparative | First light- | 15 |
| Example 2 | shielding layer | |
| | Second light- | 30 |
| | shielding layer | |
| Comparative | First light- | 60 |
| Example 3 | shielding layer | |
| | Second light- | 80 |
| | shielding layer | |

TABLE 3

| | | | | Young's | Young's | | | Etching |
|---|---|---|---|---|---|---|---|---|
| | | hardness | Hardness | modulus | modulus | Transmittance | Optical | rate |
| | Layer type | (kPa) | ratio* | (kPa) | ratio** | (%) | density | (Å/s) |
| Example 1 | First light- | 1.331 | 0.370 | 7.403 | 0.372 | 1.323 | 1.88 | 1.6 |
| | shielding | | | | | | | |
| | layer | | | | | | | |
| | Second | 0.493 | | 2.751 | | | | |
| | light- | | | | | | | |
| | shielding | | | | | | | |
| | layer | | | | | | | |
| Example 2 | First light- | 1.630 | 0.302 | 9.040 | 0.305 | 1.412 | 1.85 | 1.8 |
| | shielding | | | | | | | |
| | layer | | | | | | | |
| | Second | 0.493 | | 2.760 | | | | |
| | light- | | | | | | | |
| | shielding | | | | | | | |
| | layer | | | | | | | |
| Example 3 | First light- | 2.050 | 0.242 | 11.314 | 0.246 | 1.526 | 1.82 | 1.9 |
| | shielding | | | | | | | |
| | layer | | | | | | | |
| | Second | 0.496 | | 2.780 | | | | |
| | light- | | | | | | | |
| | shielding | | | | | | | |
| | layer | | | | | | | |
| Comparative | First light- | — | — | — | — | 1.415 | 1.85 | 1.9 |
| Example 1 | shielding | | | | | | | |
| | layer | | | | | | | |
| | Second | — | | — | | | | |
| | light- | | | | | | | |
| | shielding | | | | | | | |
| | layer | | | | | | | |
| Comparative | First light- | 1.338 | 0.618 | 7.453 | 0.621 | 1.417 | 1.85 | 1.7 |
| Example 2 | shielding | | | | | | | |
| | layer | | | | | | | |
| | Second | 0.828 | | 4.626 | | | | |
| | light- | | | | | | | |
| | shielding | | | | | | | |
| | layer | | | | | | | |
| Comparative | First light- | 1.640 | 0.102 | 9.101 | 0.101 | 0.993 | 2.02 | 1.1 |
| Example 3 | shielding | | | | | | | |
| | layer | | | | | | | |
| | Second | 0.167 | | 0.920 | | | | |
| | light- | | | | | | | |
| | shielding | | | | | | | |
| | layer | | | | | | | |

*The hardness ratio is a ratio of the hardness of the second light-shielding layer based on the hardness of the first light-shielding layer
**Young’s modulus ratio is a ratio of the Young’s modulus of the second light-shielding layer based on the Young’s modulus of the first light-shielding layer

TABLE 4

| | First light-shielding layer | | Second light-shielding layer | |
|---|---|---|---|---|
| | Separation | Adhesive | Separation | Adhesive |
| Measurement | force | force | force | force |
| points | (nN) | (fJ) | (nN) | (fJ) |
| 1 | 3.7 | 0.22 | 4.55 | 0.35 |
| 2 | 3.68 | 0.21 | 4.41 | 0.33 |
| 3 | 3.63 | 0.21 | 4.41 | 0.33 |
| 4 | 3.59 | 0.2 | 4.37 | 0.32 |
| 5 | 3.53 | 0.2 | 4.4 | 0.33 |
| 6 | 3.52 | 0.19 | 4.31 | 0.32 |
| 7 | 3.47 | 0.19 | 4.39 | 0.33 |
| 8 | 3.61 | 0.2 | 4.27 | 0.32 |
| 9 | 3.57 | 0.2 | 4.34 | 0.31 |
| 10 | 3.45 | 0.19 | 4.29 | 0.31 |
| 11 | 3.56 | 0.2 | 4.41 | 0.34 |
| 12 | 3.45 | 0.19 | 4.36 | 0.33 |
| 13 | 3.36 | 0.18 | 4.37 | 0.33 |
| 14 | 3.52 | 0.19 | 4.29 | 0.3 |
| 15 | 3.49 | 0.19 | 4.18 | 0.3 |
| 16 | 3.47 | 0.19 | 4.27 | 0.3 |
| Average | 3.538 | 0.197 | 4.351 | 0.322 |
| Standard | 0.091 | 0.010 | 0.084 | 0.015 |
| deviation | | | | |
| Ratio of standard | 2.567 | 5.153 | 1.935 | 4.569 |
| deviation to | | | | |
| average (%) | | | | |

In FIG. 5, the surface reflectance of the light-shielding film of Example 1 exhibited a reflectance of 25% or more and 35% or less at a wavelength of 190 nm or more and 260 nm or less, exhibited a reflectance of 30% or more and 45% or less at a wavelength of 350 nm or more and 400 nm or less, and exhibited a reflectance of 35% or more and 45% or less at a wavelength of 480 nm or more and 550 nm or less.

In Table 3, the hardness ratio in Examples 1 to 3 was 0.15 or more and 0.55 or less, whereas the hardness ratio in Comparative Example 1 was greater than 0.6 and the hardness ratio in Comparative Example 2 was less than 0.11.

The Young's modulus ratio in Examples 1 to 3 was 0.15 or more and 0.55 or less, whereas the Young's modulus ratio in Comparative Example 1 was greater than 0.6 and the Young's modulus ratio in Comparative Example 2 was less than 0.11.

In the etching rate, Examples 1 to 3, Comparative Examples 1 and 2 showed a rate of 1.6 Å/s or more, whereas the etching rate of Comparative Example 3 was 1.1 Å/s.

In the evaluation of the adhesive force and separation force, a ratio of the standard deviation to the average value of the separation force of the first light-shielding layer and the second light-shielding layer of Example 2 was 3% or less, respectively, and a ratio of the standard deviation to the average value of the adhesive force thereof was 6% or less, respectively.

In FIGS. 6A and 6B, it was confirmed that the surface of Comparative Example 1 had a number of particles and scratches caused by the particles. It was confirmed that, on the surface of Comparative Example 2, the size and number of particles were relatively reduced compared to those in Comparative Example 1, but a significant number of particles were still generated.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A blank mask comprising:
a light-transmitting substrate; and
a light-shielding film, disposed on the light-transmitting substrate, comprising a first light-shielding layer and a second light-shielding layer disposed on the first light-shielding layer,
wherein the second light-shielding layer includes at least one of a transition metal, oxygen, or nitrogen, or any combination thereof,
a reflectance of a surface of the light-shielding film with respect to light having a wavelength of 193 nm is 20% or more and 40% or less, and
a hardness value of the second light-shielding layer is 0.3 kPa or more and 0.55 kPa or less.

2. The blank mask of claim 1, wherein a reflectance of the surface of the light-shielding film with respect to light having a wavelength of 350 nm is 25% or more and 45% or less.

3. The blank mask of claim 1, wherein:
a reflectance of the surface of the light-shielding film with respect to all light having a wavelength of 350 nm or more and 400 nm or less is included in a range of 25% or more and 50% or less; and
a reflectance of the surface of the light-shielding film with respect to all light having a wavelength of 480 nm or more and 550 nm or less is included in a range of 30% or more and 50% or less.

4. The blank mask of claim 1, wherein the hardness value of the second light-shielding layer is 0.15 times or more and 0.55 times or less than a hardness value of the first light-shielding layer.

5. The blank mask of claim 1, wherein a Young's modulus value of the second light-shielding layer is 1.0 kPa or more.

6. The blank mask of claim 1, wherein a Young's modulus value of the second light-shielding layer is 0.15 times or more and 0.55 times or less than a Young's modulus value of the first light-shielding layer.

7. The blank mask of claim 1, wherein an absolute value of a value obtained by subtracting a transition metal content of the first light-shielding layer from a transition metal content of the second light-shielding layer is 30 at % or less.

8. The blank mask of claim 1, wherein a thickness ratio of the first light-shielding layer and the second light-shielding layer is 1:0.02 to 0.25.

9. The blank mask of claim 1, wherein a film thickness of the second light-shielding layer is 30 to 200 Å.

10. The blank mask of claim 1, wherein the second light-shielding layer includes the transition metal at 35 at % or more and 75 at % or less.

11. The blank mask of claim 1, wherein the transition metal includes at least one selected from the group consisting of Cr, Ta, Ti, and Hf.

12. A photomask comprising:
a light-transmitting substrate; and
a patterned light-shielding film, disposed on the light-transmitting substrate, comprising a first light-shielding layer and a second light-shielding layer disposed on the first light-shielding layer,
wherein the second light-shielding layer includes at least one of a transition metal, oxygen, or nitrogen, or any combination thereof,
a reflectance of an upper surface of the patterned light-shielding film with respect to light having a wavelength of 193 nm is 20% or more and 40% or less, and
a hardness value of the second light-shielding layer is 0.3 kPa or more and 0.55 kPa or less.

13. A method of manufacturing a semiconductor device, the method comprising:
arranging a light source, a photomask, and a semiconductor wafer coated with a resist film;
selectively transmitting and emitting light incident from the light source through the photomask on the semiconductor wafer; and
developing a pattern on the semiconductor wafer,
wherein the photomask includes a light-transmitting substrate and a patterned light-shielding film disposed on the light-transmitting substrate,
the patterned light-shielding film includes a first light-shielding layer and a second light-shielding layer disposed on the first light-shielding layer,
the second light-shielding layer includes at least one of a transition metal and at least one of oxygen and nitrogen,
a reflectance of an upper surface of the patterned light-shielding film with respect to light having a wavelength of 193 nm is 20% or more and 40% or less, and
a hardness value of the second light-shielding layer is 0.3 kPa or more and 0.55 kPa or less.
